(19) United States
(12) Patent Application Publication
(10) Pub. No.: US 2014/0374807 A1
(43) Pub. Date: Dec. 25, 2014

(54) METHOD OF DEVICE ISOLATION IN CLADDING Si THROUGH IN SITU DOPING

(71) Applicants: International Business Machines Corporation, Armonk, NY (US); GLOBALFOUNDRIES Inc., Grand Cayman (KY)

(72) Inventors: Ajey Poovannummoottil Jacob, Albany, NY (US); Murat Kerem Akarvardar, Saratoga Springs, NY (US); Bruce B. Doris, Slingerlands, NY (US); Ali Khakifirooz, Mountain View, CA (US)

(21) Appl. No.: 13/921,265

(22) Filed: Jun. 19, 2013

(51) Int. Cl. H01L 29/78; H01L 21/02

(52) U.S. Cl. CPC H01L 29/785; H01L 21/02532
USPC 257/288; 438/478

(57) ABSTRACT

Aspects of the present invention relate to an approach for forming an integrated circuit having a set of fins on a silicon substrate, with the set of fins being formed according to a predetermined pattern. In situ doping of the fins with an N-type dopant prior to deposition of an epitaxial layer minimizes punch through leakage whilst an epitaxial depositional process applies a cladding layer on the doped fins, the deposition resulting in a multigate device having improved device isolation.

### BACKGROUND OF THE INVENTION

1. Technical Field

The present invention relates generally to semiconductor fabrication and, more particularly, to in situ doping of Si fins prior to silicon-germanium (SiGe) cladding to reduce punch through leakage.

2. Related Art

The fin-shaped field effect transistor (FinFET) is a transistor design that attempts to overcome the issues of short-channel effect encountered by deep submicron transistors, such as drain-induced barrier lowering (DIBL). Such effects make it harder for the voltage on a gate electrode to deplete the channel underneath and stop the flow of carriers through the channel—in other words, to turn the transistor off. By raising the channel above the surface of the wafer instead of creating the channel just below the surface, it is possible to wrap the gate around all but one of its sides, providing much greater electrostatic control over the carriers within it.

FinFET architecture typically takes advantage of self-aligned process steps to produce extremely narrow features that are much smaller than the wavelength of light that is generally used to pattern devices on a silicon wafer. It is possible to create very thin fins of 20 nm in width or less on the surface of a silicon wafer using selective-etching processes, although they typically cannot currently be made less than 20 nm to 30 nm because of the current limits of lithographic resolution. The fin is used to form the raised channel. The gate is then deposited so that it wraps around the fin to form a trigate structure. As the channel is extremely thin, the gate typically has much greater control over the carriers within it. However, when the device is switched on, the gate shape limits the current through the gate to a low level. Consequently, multiple fins may be used in parallel to provide higher drive strengths.

Originally, the FinFET was developed for use on silicon-on-insulator (SOI) wafers. Recent developments have made it possible to produce working FinFETs on bulk silicon wafers and to improve the performance of certain parameters thereof. The steep doping profile typically used to control leakage into the bulk substrate has a beneficial impact on drain induced barrier lowering (DIBL).

### SUMMARY OF THE INVENTION

In general, aspects of the present invention relate to an approach for using a dopant to provide increased device isolation by the use of in situ doping prior to SiGe cladding depositional application.

A first aspect of the present invention provides a method for forming an integrated circuit using the steps of first forming a set of fins on a silicon substrate in a predetermined pattern, doping the set of fins in situ with an N-type dopant, and subsequently growing an epitaxial cladding layer over the doped fins to form a multigate semiconductor device.

A second aspect of the present invention provides a method for forming an integrated circuit using the steps of first forming a set of fins on a silicon substrate in a predetermined pattern, doping the fins in situ with an N-type dopant, disposing a carbon liner on the fins; and then growing an epitaxial cladding layer over the carbon liner to form a multigate semiconductor device.

### BRIEF DESCRIPTION OF THE DRAWINGS

These and other features of this invention will be more readily understood from the following detailed description of the various aspects of the invention taken in conjunction with the accompanying drawings in which:

FIG. 1 is a flow chart showing the steps of a first embodiment of a prior art method of processing a finned Si substrate;

FIGS. 2A-2D are side sectional, schematic views of the steps of the prior art processing method of FIG. 1;

FIG. 3A is a flow chart showing the steps of a first embodiment of the present invention;

FIG. 3B is a flow chart showing the steps of a second embodiment of the present invention, and

FIGS. 4A-4F depict side sectional, schematic views of a FinFET method of cladding and epitaxial SiGe deposition on a silicon fin according to embodiments of the present invention.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbers represent like elements.

### DETAILED DESCRIPTION OF THE INVENTION

Illustrative embodiments will now be described more fully herein with reference to the accompanying drawings, in which embodiments are shown. This disclosure may, however, be embodied in many different forms and should not be construed as limited to the embodiments set forth herein. Rather, these embodiments are provided so that this disclosure will be thorough and complete and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to limit this disclosure. As used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The term “set” is intended to mean a quantity of at least one. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer) is present on a second element, such as a second structure (e.g. a second layer) wherein intervening elements, such as an interface structure (e.g. interface layer) may be present between the first element and the second element.

Planar transistors have been the core of integrated circuits for several decades, during which the size of the individual transistors has steadily decreased. As the size decreases, planar transistors typically increasingly suffer from the undesirable short-channel effect, especially “off-state” leakage current. Such currents increase the idle power required by the device.

In a multigate device, the channel is surrounded by several gates on multiple surfaces, allowing more effective suppression of “off-state” leakage current. Multiple gates also allow increased drive current in the “on” state. These advantages translate to lower power consumption and enhanced device performance. Nonplanar devices are typically more compact than conventional planar transistors, thereby enabling higher transistor density that translates to smaller overall sizes for microelectronic devices.

As stated above, aspects of the present invention relate to an approach for using a dopant for increased device isolation by the use of in situ doping of the silicon fins prior to SiGe cladding deposition. Specifically, prior to the SiGe cladding application, an appropriate N-type in situ doping of the silicon fin is performed. In a second exemplary embodiment of the present invention, appropriate N-type in situ doping is performed, and in addition, a carbon liner over the fin prevents dopant diffusion from the Si fin during subsequent depositions.

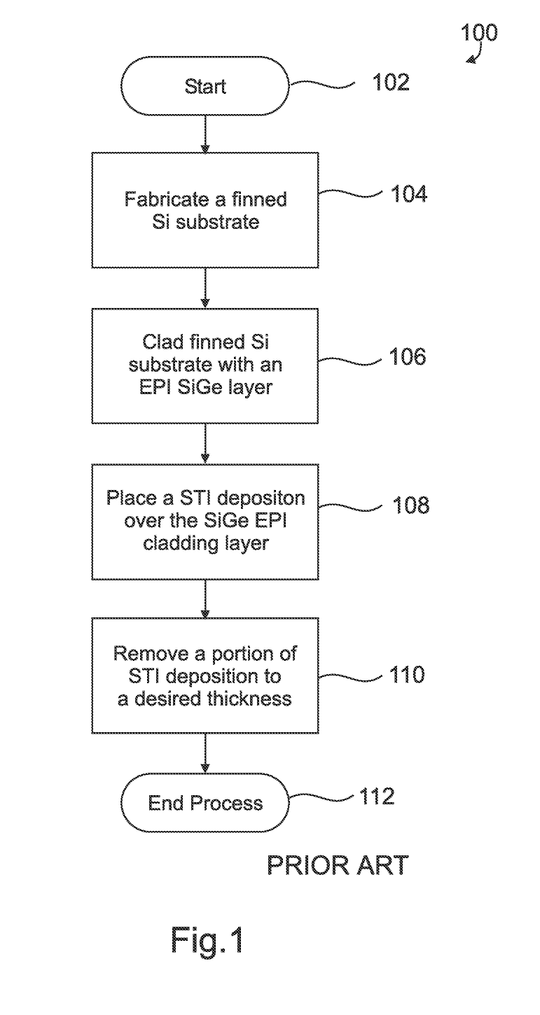

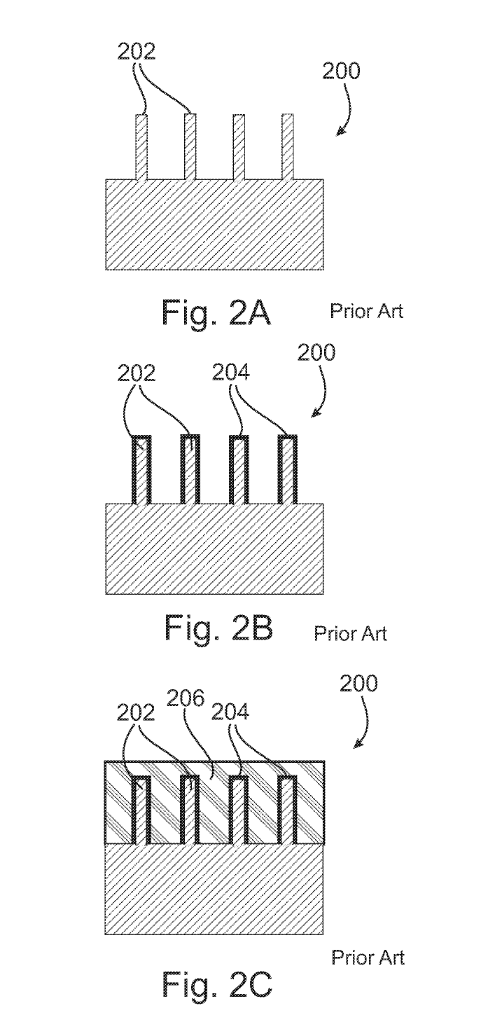

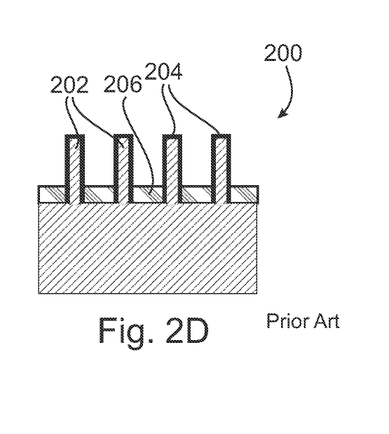

Referring now to FIG. 1, there is shown a flow chart of the steps of a prior art approach for creating a multi-gate device on a finned Si substrate. FIGS. 2A-2D are side sectional, schematic views showing the results of respective steps of the prior art approach of FIG. 1.

The process is started at block 102. A finned Si substrate is provided at block 104. FIG. 2A shows an Si substrate 200 prior to subsequent processing. Individual fins 202 are created using processes believed to be well known to those of skill in the art. Fins 202 are generally formed in at least one parallel line of fins according to a predetermined pattern, depending on the end use of the substrate. Such fin-creating processes include, but are not limited to, shallow trench isolation (STI).

The finned Si substrate 200 has an epitaxial (EPI) SiGe cladding applied at block 106. FIG. 2B shows cladding 204 applied to an upper surface of substrate 200 and to fins 202. Cladding 204 is typically formed by an epitaxial depositional process that grows an SiGe cladding layer 204 thereon fin 202.

Once cladding 204 is formed at block 106, an STI deposition is made at block 108. FIG. 2C shows EPI deposition 206 in place over SiGe cladding 204. STI deposition techniques are believed to be well known to those of skill in the art.

Once the STI deposition is complete, the oxide (i.e., STI deposit) is reduced to a desired thickness in trenches, not specifically identified, between fins 202 at block 110 as shown in FIG. 2D. Possible known processes for such reduction include, but are not limited to, dry etching and chemical-mechanical polishing (CMP).

It will be recognized that the steps of blocks 108 and 110 may be combined and an STI layer of the desired thickness may be deposited using a lithographic process or another trench fill with oxide process, both believed to be well known to those of skill in the art. The process is ended at block 112.

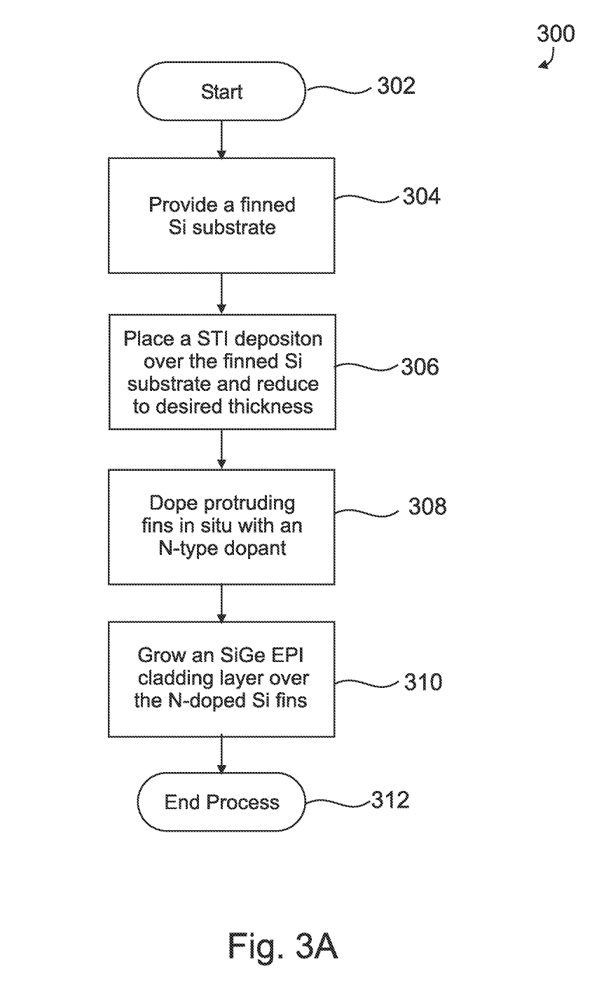

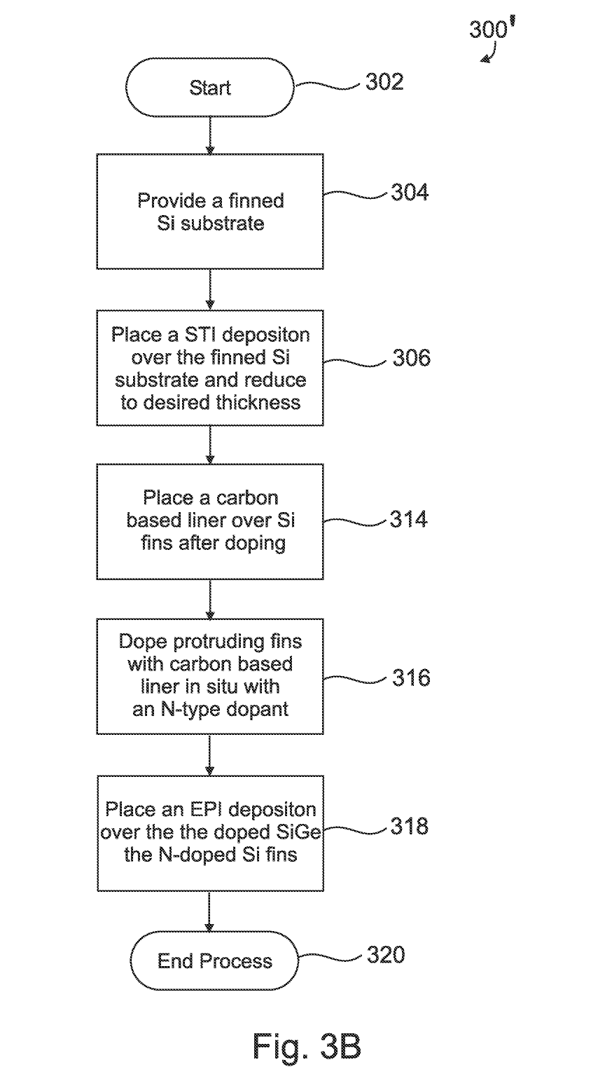

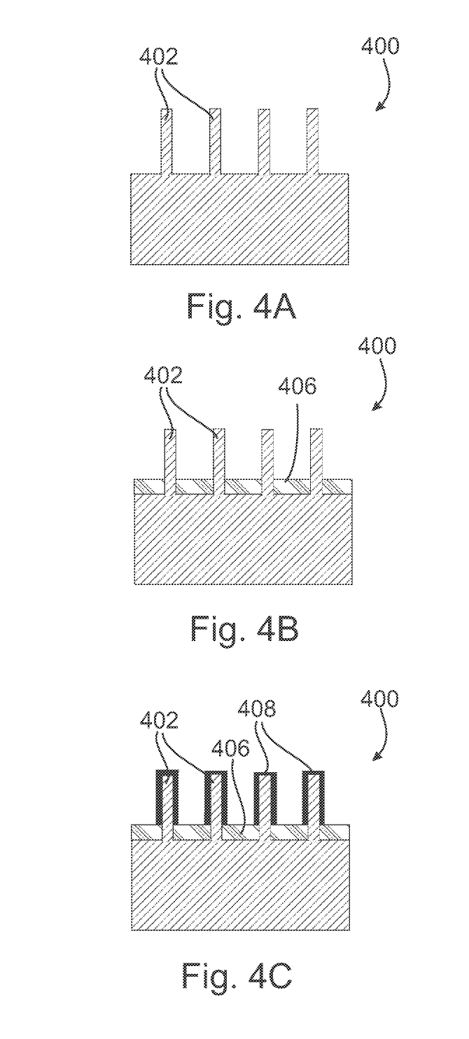

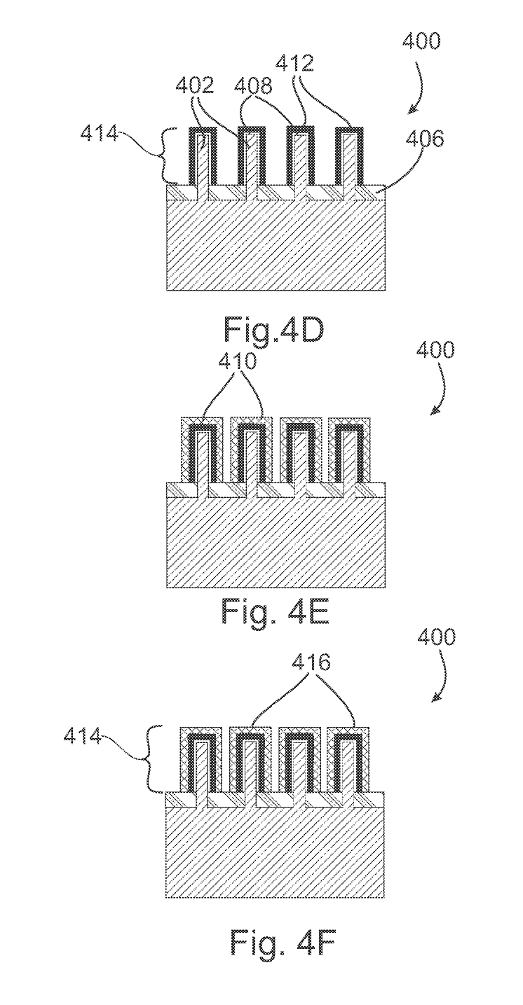

Referring now also to FIG. 3A, there is shown a flow chart of the steps of a first embodiment of the novel processing method of the invention, generally at reference number 300. FIGS. 4A-4C and 4E are side sectional, schematic views of the results of respective processing steps shown in the flowchart of FIG. 3A.

The process is started at block 302. A first embodiment of the novel processing method begins with supplying a finned Si substrate at block 304. FIG. 4A shows the finned Si substrate 400 with fins 402 prior to any processing. Individual fins 402 are created using processes believed to be well known to those of skill in the art. Fins 402 are generally formed in at least one parallel line of fins according to a predetermined pattern, depending on the end use of the substrate. Such fin-creating processes include but are not limited to, shallow trench isolation (STI).

Next, an STI layer 406 is formed over the finned Si substrate 400 and the STI layer 406 reduced to a predetermined thickness in trenches, not specifically identified, between Si fins 402, at block 306. STI layer 406 is seen in FIG. 4B. As discussed hereinabove, STI may be deposited in a thick overall layer or, alternatively, a thin layer of oxide may be deposited in the trenches between fins 402.

Once STI layer 406 is deposited and reduced to a predetermined thickness, an appropriate N-type doping is performed in situ at block 308. FIG. 4C schematically represents the doped Si fins at reference number 408. This process step minimizes the band offset between the silicon fin 402 and the SiGe cladding 410, as shown in FIG. 4E, while preventing leakage current through the silicon fin bulk. N-type dopants, for example, phosphorus, are believed to be well known to those of skill in the art and, consequently, are not further discussed nor described herein.

The doping process introduces a small percentage of foreign atoms into the regular crystal lattice of silicon or germanium. Such doping typically produces dramatic changes in the semiconductor's (e.g., Si or Ge) electrical properties, producing n-type and p-type semiconductors. For example, impurity atoms with 5 valence electrons produce n-type semiconductors by contributing extra electrons. The addition of pentavalent impurities such as antimony, arsenic or phosphorous during doping contributes free electrons, greatly increasing the conductivity of the intrinsic semiconductor. Phosphorous may be added by diffusion of phosphine gas (PH3). Other N-type dopants may be added using techniques believed to be well known to those of skill in the semiconductor arts.

It will be recognized that any suitable N-type dopant may be used and the invention is not considered limited to any particular N-type dopant. Consequently, the invention is seen to include any suitable N-type dopant.

Once in situ doping (block 308), is complete, an SiGe EPI cladding layer 410 is grown over doped Si fins 402, block 310. FIG. 4D shows epitaxial layer 410 over N-doped Si fins. The process is ended at block 312.

Referring now also to FIG. 3B, there is shown a flow chart of the steps of a second embodiment of the novel processing method of the invention, generally at reference number 300′. FIGS. 4A-4B, 4D and 4F are side sectional, schematic views of the results of respective processing steps shown in the flowchart 300′ of FIG. 3B.

The process is started at block 302. Like the first embodiment of the novel processing method shown in FIG. 3A, the second embodiment begins with supplying a finned Si, substrate at block 304. FIG. 4A shows the finned Si substrate 400 with fins 402 prior to any processing. Individual fins 402 are created using processes believed to be well known to those of skill in the art. Fins 402 are generally formed in at least one parallel line of fins according to a predetermined pattern, depending on the end use of the substrate. Such fin-creating processes include but are not limited to, shallow trench isolation (STI).

Next, an STI layer 406 is formed over the finned Si substrate 400 and STI layer 406 is reduced to a predetermined thickness in the trenches, not specifically identified, between Si fins 402, at block 306. STI layer 406 is seen in FIG. 4B. As discussed hereinabove, STI may be deposited in a thick overall layer or, alternatively, a thin layer of oxide may be deposited in the trenches between fins 402.

In this embodiment, a carbon cap or liner 412 is formed over the Si fins 402 prior to doping at block 314. FIG. 4D shows a carbon cap 412 over Si fins 402. It will be appreciated that carbon liner 412 formed over Si fins 402 is effective at decreasing each of the following: dopant diffusion, punch through leakage, and electrostatic charge distribution.

Once carbon cap 412 is fabricated at block 314, the capped Si fins are doped with an N-type dopant at block 316. In addition to showing carbon cap 412, FIG. 4D shows doped, carbon capped fins at reference number 414.

Finally, a SiGe EPI cladding layer 416 is grown over doped Si fins 414 at block 318. FIG. 4F shows SiGe EPI cladding layer 416 grown over doped Si fins 414. The process is ended at block 320.

In various embodiments, design tools can be provided and configured to create the data sets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines, or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations.

Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention.

In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method for forming an integrated circuit, the steps comprising:
forming a set of fins on a silicon substrate, said set of fins being formed according to a predetermined pattern;
performing in situ doping of said set of fins with an N-type dopant; and
growing an epitaxial cladding layer on said doped fins, the epitaxial deposition resulting in a multigate device.

2. The method of claim 1, wherein said performing in situ doping step comprises doping with at least one N-type dopant selected from the group of: pentavalent impurities, antimony, arsenic, and phosphorous.

3. The method of claim 1, wherein said growing an epitaxial cladding layer step comprises growing a silicon-germanium (SiGe) cladding layer.

4. The method of claim 1, wherein said forming a set of fins comprises forming a set of fins in a predetermined pattern comprising at least one parallel line of fins on said silicon substrate surface.

5. The method of claim 2, wherein said performing in situ doping step improves at least one selected from the group: band offset between the silicon fin and SiGe cladding, punch through leakage, and electrostatic charge distribution.

6. The method of claim 1, wherein said forming a set of fins, performing in situ doping, and growing an epitaxial cladding layer steps produce a fin field-effect transistor (FinFET).

7. A method for forming an integrated circuit, comprising:
forming a set of fins on a silicon substrate, said set of fins being formed according to a predetermined pattern;
performing in situ doping of at least said set of fins with an N-type dopant;
disposing a carbon liner on said fins; and
growing an epitaxial cladding layer on said carbon liner, the deposition resulting in a multigate device.

8. The method of claim 7, wherein said performing in situ doping step comprises performing in situ doping with at least one N-type dopant selected from the group: pentavalent impurities, antimony, arsenic, and phosphorous.

9. The method of claim 7, wherein said disposing a carbon liner on said fins decreases each of the following: dopant diffusion, punch through leakage, and electrostatic charge distribution.

10. The method of claim 9, wherein said disposing a carbon liner on said fins comprises disposing a carbon line on all exposed surfaces of said fins above an STI layer.

11. The method of claim 7, wherein said growing an epitaxial cladding layer comprises growing a silicon-germanium (SiGe) cladding layer.

12. The method of claim 8, wherein said performing in situ doping improves at least one of: band offset between the silicon fin and SiGe cladding, punch through leakage, and electrostatic charge distribution.

13. The method of claim 7, wherein said forming a set of fins, performing in situ doping, and growing an epitaxial cladding layer produce a fin field-effect transistor (FinFET).

14. An integrated circuit, comprising:
a silicon substrate;
a dopant entrained in said silicon substrate;
at least one finned region over said silicon substrate, said at least one finned region being defined by at least two trenches formed by shallow trench isolation (STI), said at least two trenches being formed according to a predetermined pattern, and said at least one finned region resulting in fin surfaces having a first vertical wall defined by a first of said at least two trenches and a second vertical wall defined by a second of said at least two trenches; and
a carbon liner formed along the fin surfaces and atop a STI layer formed within the at least two trenches.

15. (canceled)

16. The integrated circuit of claim 14, further comprising a cladding layer formed over the carbon liner.

17. The integrated circuit of claim 14, wherein said at least one finned region comprises a fin field-effect transistor (FinFET).

18. The integrated circuit of claim 14, wherein said dopant is selected from the group of: pentavalent impurities, antimony, arsenic, and phosphorous.

19. The integrated circuit of claim 15, wherein said carbon liner extends along the fin surfaces to a top surface of the STI layer.

20. The integrated circuit of claim 15, wherein said carbon liner covers only a section of the fin surfaces projecting above an STI layer.
